(19) United States
(12) Patent Application Publication
(10) Pub. No.: US 2025/0204268 A1
(43) Pub. Date: Jun. 19, 2025

(54) CONCAVE TRAY BOTTOM ELECTRODE FOR MRAM

(71) Applicant: INTERNATIONAL BUSINESS MACHINES CORPORATION, Armonk, NY (US)

(72) Inventors: Oscar van der Straten, Guilderland Center, NY (US); Chih-Chao Yang, Glenmont, NY (US)

(21) Appl. No.: 18/539,532

(22) Filed: Dec. 14, 2023

(51) Int. Cl. H10N 50/80; H10B 61/00; H10N 50/01; H10N 50/10

(52) U.S. Cl. CPC H10N 50/80; H10B 61/10; H10N 50/01; H10N 50/10

(57) ABSTRACT

A magnetoresistive random access memory (MRAM) includes a magnetic tunnel junction (MTJ) having a reference layer, a free layer and a tunnel barrier disposed between the reference layer and the free layer. A bottom electrode is centrally disposed to be located within a periphery of the MTJ. The bottom electrode has sloped sidewalls that slope inwardly to connect to the MTJ.

### BACKGROUND

The present invention generally relates to magnetic memory devices, and more particularly to a magnetic memory device having a concave tray back electrode that reduces risk of shorts due to re-sputtered electrode materials.

For high performance magnetoresistive random access memory (MRAM) devices based on perpendicular magnetic tunnel junction (MTJ) structures, well-defined interfaces and interface control are important factors. MTJ structures may include a Co-based synthetic anti-ferromagnet (SAF), a CoFeB-based reference layer, a MgO-based tunnel barrier, a CoFeB-based free layer, and cap layers containing, e.g., Ta and/or Ru. Embedded MTJ structures are usually formed by subtractive patterning of blanket MTJ structures into pillars between two metal levels.

After MTJ structure patterning, a bottom electrode is patterned by etching away excess metal to match the dimensions of the MTJ structure. This processing of the back electrode results in re-sputtering of metal materials. The metal materials are disbursed and can redeposit on an exterior of the MTJ structure. This can result in MTJ shorts or require additional processing to remove re-sputtered materials.

Therefore, a need exists for a back electrode that minimizes risk of shorts due to the redeposition of metal material on an MTJ structure during the formation of the back electrode.

### SUMMARY

In accordance with an embodiment of the present invention, a magnetoresistive random access memory (MRAM) includes a magnetic tunnel junction (MTJ) having a reference layer, a free layer and a tunnel barrier disposed between the reference layer and the free layer. A bottom electrode is centrally disposed to be located within a periphery of the MTJ. The bottom electrode has sloped sidewalls that slope inwardly to connect to the MTJ.

In some embodiments, the sloped sidewalls define a volume, and the volume is filled with a dielectric material. The bottom electrode can be disposed within a dielectric layer, and the dielectric layer extends to the periphery of the MTJ. The dielectric layer is not present and is therefore free of the bottom electrode outside the periphery. The sloped sidewalls can form an acute angle with a bottom portion of the bottom electrode. The sloped sidewalls can include a concave profile. The bottom electrode can include at least two layers of conductive material. The at least two layers of conductive material can include at least two layers of different conductive materials.

In accordance with another embodiment of the present invention, an MRAM includes a metal cap, a bottom electrode having sloped sidewalls that define a dielectric-filled volume and a MTJ having a reference layer, a free layer and a tunnel barrier disposed between the reference layer and the free layer. The MTJ has a periphery. The bottom electrode is centrally disposed to be located within the periphery. The sloped sidewalls slope inwardly to connect to the MTJ and outwardly to connect to the metal cap.

In some embodiments, the bottom electrode can be disposed within a dielectric layer and the dielectric layer extends to the periphery of the MTJ. The dielectric layer can be free of the bottom electrode outside the periphery. The sloped sidewalls of the bottom electrode can be connected at a bottom portion of the bottom electrode. The sloped sidewalls can include a concave profile. The bottom electrode can include at least two layers of conductive material. The at least two layers of conductive material can include at least two layers of different conductive materials. The sloped sidewalls can form an acute angle with a bottom portion of the bottom electrode.

In accordance with an embodiment of the present invention, a method for making a MRAM includes forming a mandrel for a bottom electrode; depositing a first dielectric layer over the mandrel; pulling the mandrel to form a cavity having an opening; conformally depositing a bottom electrode layer in the cavity; filling the cavity with a dielectric material; planarizing the dielectric material and the bottom electrode layer to form the bottom electrode in the cavity; and patterning a MTJ stack by etching through the MTJ stack and the first dielectric layer without exposing the bottom electrode.

In other embodiments, conformally depositing the bottom electrode layer in the cavity can include conformally depositing a plurality of bottom electrode layers in the cavity. Forming the mandrel for a bottom electrode can include forming concave sidewalls for the mandrel. The first dielectric layer can include a peripheral region that is free of the bottom electrode.

In accordance with an embodiment of the present invention, a MRAM includes a bottom electrode on a metal cap, the bottom electrode having sloped sidewalls that define a dielectric-filled volume, the bottom electrode being centrally disposed on the metal cap and having sloped sidewalls sloping inwardly to connect to a ferromagnetic layer.

In other embodiments, the bottom electrode can be disposed within a dielectric layer, and the dielectric layer can extend to a periphery of the ferromagnetic layer. The dielectric layer is free of material of the bottom electrode outside the periphery. The sloped sidewalls can include a concave profile. The bottom electrode can include at least two layers of conductive material.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view showing a dielectric layer formed on a conductor in accordance with an embodiment of the present invention;

FIG. 2 is a cross-sectional view showing the dielectric layer patterned to reveal an underlying conductor in accordance with an embodiment of the present invention;

FIG. 3 is a cross-sectional view showing a cap conductor formed through the dielectric layer in accordance with an embodiment of the present invention;

FIG. 4 is a cross-sectional view showing a cap formed on the conductors in accordance with an embodiment of the present invention;

FIG. 5 is a cross-sectional view showing a mandrel layer deposited for creating a form for a bottom electrode in accordance with an embodiment of the present invention;

FIG. 6 is a cross-sectional view showing a hard mask formed to pattern the mandrel layer in accordance with an embodiment of the present invention;

FIG. 7 is a cross-sectional view showing the mandrel layer patterned into a mandrel having sloped or concave sidewalls in accordance with an embodiment of the present invention;

FIG. 8 is a cross-sectional view showing the hard mask removed and a dielectric layer formed to bury the mandrel in accordance with an embodiment of the present invention;

FIG. 9 is a cross-sectional view showing the dielectric layer planarized to open a top to expose the mandrel in accordance with an embodiment of the present invention;

FIG. 10 is a cross-sectional view showing a mandrel pull to provide a form for fabricating a bottom electrode with sloping sidewalls in accordance with an embodiment of the present invention;

FIG. 11 is a cross-sectional view showing a conformal electrode layer conformally deposited in a cavity and on a surface of the dielectric layer in accordance with an embodiment of the present invention;

FIG. 12 is a cross-sectional view showing the cavity filled with a dielectric material in accordance with an embodiment of the present invention;

FIG. 13 is a cross-sectional view showing excess dielectric material and the conformal electrode layer planarized to open a top of the conformal electrode layer and form the sloped sidewall bottom electrode in accordance with an embodiment of the present invention;

FIG. 14 is a cross-sectional view showing a magnetic tunnel junction stack formed in accordance with an embodiment of the present invention;

FIG. 15 is a cross-sectional view showing a top electrode conductor formed on the magnetic tunnel junction stack in accordance with an embodiment of the present invention;

FIG. 16 is a cross-sectional view showing a hard mask formed for patterning the MTJ stack and the dielectric layer in accordance with an embodiment of the present invention;

FIG. 17 is a cross-sectional view showing the MTJ stack and the dielectric layer patterned without etching any conductive material as the sloped sidewall bottom electrode is centrally disposed within a periphery of the MTJ in accordance with an embodiment of the present invention;

FIG. 18 is a cross-sectional view showing an encapsulation dielectric layer formed over an MTJ and a top electrode in accordance with an embodiment of the present invention;

FIG. 19 is a cross-sectional view showing an etch-back to form dielectric sidewalls on sides of the MTJ in accordance with an embodiment of the present invention;

FIG. 20 is a cross-sectional view showing an interlevel dielectric layer formed in accordance with an embodiment of the present invention;

FIG. 21 is a cross-sectional view showing a conductive layer deposited to form a top conductor in accordance with an embodiment of the present invention;

FIG. 22 is a cross-sectional view showing two conformal electrode layers conformally deposited in a cavity and over a surface of the dielectric layer in accordance with an embodiment of the present invention;

FIG. 23 is a cross-sectional view showing the cavity filled with a dielectric material in accordance with an embodiment of the present invention;

FIG. 24 is a cross-sectional view showing a sloped sidewall bottom electrode having multiple layers in accordance with an embodiment of the present invention; and

FIG. 25 is a cross-sectional view showing an MRAM device with a sloped sidewall bottom electrode having multiple layers in accordance with an embodiment of the present invention.

### DETAILED DESCRIPTION

Embodiments of the present invention include magnetic devices having back electrodes with a sloped or concave sidewall profile. The back electrode (also referred to herein as a sloped sidewall bottom electrode) occupies a central location within boundaries of a magnetic tunnel junction (MTJ) to avoid placement of metal materials at or near a periphery of the MTJ. In this way, the back electrode is not etched at the periphery and can avoid re-sputtering of metal materials that make up the back electrode. By removing the etch process to pattern the back electrode, the MTJ will experience a significant reduction or even elimination of shorts with the MTJ due to re-sputtering. In useful embodiments, the magnetic device includes a magnetoresistive random-access memory (MRAM) device.

In one embodiment, the MRAM device or cell can include an MTJ, a top electrode and a sloped sidewall bottom electrode. The sloped sidewall bottom electrode can include a concave tray shape, a trapezoidal cross-sectional shape, a conical shape or a sloped wall shape. The sloped sidewall bottom electrode includes a horizontal portion, which is part of or connects to the sidewalls. The sloped sidewall bottom electrode can include a metal nitride, such as, e.g., TaN, TiN, or a metal, such as, e.g., W, Ru, Pt, etc. The sloped sidewall bottom electrode can be deposited using chemical vapor deposition (CVD), atomic layer deposition (ALD) or any suitable deposition method. The sloped sidewall bottom electrode can include a single layer or multiple layers.

In an embodiment, the sloped sidewall bottom electrode can be hollow and filled with a dielectric material. The sloped sidewall bottom electrode can also be buried within a dielectric material or layer. The dielectric material and/or layer can include, e.g., SiON, AlON, or metal oxides such as, TiO₂, Al₂O₃, HfO₂. Combinations of these and other materials are also contemplated. CVD, plasma enhanced CVD (PECVD) and/or ALD can be employed for depositing the dielectric material.

In an embodiment, methods for forming the back electrode include forming a mandrel by a mandrel deposition and performing a tapered etch on the mandrel to obtain a shape for the sloped sidewall bottom electrode. Dry etch methods, such as, e.g., reactive ion etching (RIE) and wet etch methods can be employed to enable a mandrel etch and pull. A bottom electrode dielectric layer is deposited to bury the mandrel followed by a planarization process.

A mandrel pull removes the mandrel from the dielectric layer and leaves a void shaped like the sloped sidewall bottom electrode to be formed. The sloped sidewall bottom electrode is deposited to line the void with a metal layer. A second dielectric layer is deposited to fill remaining portions of the void. The excess dielectric and metal are planarized to level off a free surface of the device. MTJ stack deposition and patterning are performed with little or no metal re-sputtering risk from the sloped sidewall bottom electrode. Processing can continue with a deposition of a dielectric for MTJ encapsulation and the dielectric etch-back. Then, an interlevel dielectric layer (ILD) is deposited and patterned for top contact formation.

Embodiments of the present invention extend scalability of MRAM/memory elements due to an enlarged process window for MRAM stack patterning. In addition, performance improvements can be achieved for embedded MRAM devices due to reduced tunnel barrier shorts.

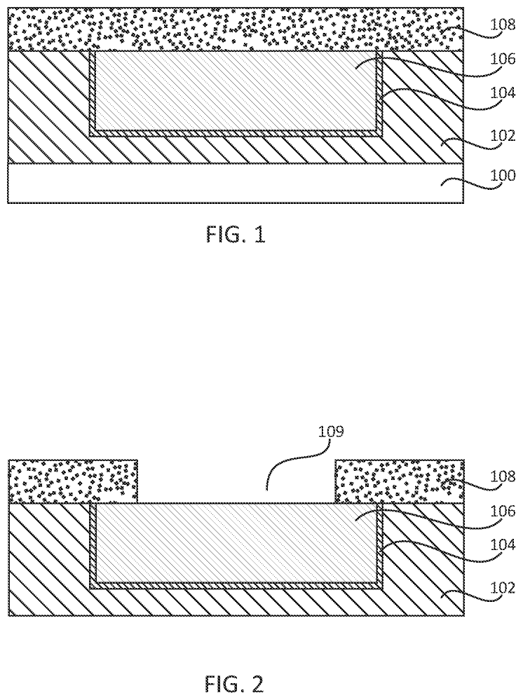

Referring now to the drawings in which like numerals represent the same or similar elements and initially to FIG. 1, methods for manufacturing a magnetoresistive random access memory (MRAM) cell is shown in accordance with embodiments of the present invention. The MRAM cell includes a substrate 100 having multiple layers on which the MRAM cell will be fabricated. The substrate 100 can include any suitable substrate structure, e.g., a bulk semiconductor, a semiconductor-on-insulator (SOI) substrate, etc. In one example, the substrate 100 can include a silicon-containing material. Illustrative examples of Si-containing materials suitable for the substrate 100 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

While the substrate 100 can include a single semiconductor layer, the substrate 100 can also be comprised of a plurality of different layers including one or more front end of line (FEOL) layers, one or more middle of the line layers (MOL) and/or one more back end of line (BEOL) layers. These layers may, in turn, include one or more active device layers, one or more dielectric layers, one or more metal layers, etc.

A dielectric layer 102, such as, e.g., an interlevel dielectric layer (ILD) is formed on the substrate 100. The dielectric layer 102 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 102 can be deposited using chemical vapor deposition (CVD), although other deposition methods can be employed.

The deposited dielectric layer 102 is then patterned and etched to form a hole or trench. The trench is then lined with a metal liner or diffusion barrier 104. The diffusion barrier 104 can be conformally deposited over the topography of the dielectric layer 102. The diffusion barrier 104 can be deposited by an atomic layer deposition (ALD) process, physical vapor deposition (PVD) or a CVD process, although other processes may be employed. The diffusion barrier 104 can include a material such as, e.g., TiN, TaN, TiWN, TaWN, HfN or the like.

A conductive fill is performed to fill the trenches on top of the diffusion barrier 104. The conductive fill can include materials, such as, e.g., Cu, Ru, Mo, Rh, W, Ir, and alloys or combinations of these and other conductive materials. In a particularly useful embodiment, the conductive fill includes Ru. The conductive fill can be formed using a deposition method, such as, e.g., CVD, plasma enhanced CVD (PECVD), ALD or any other suitable deposition method.

A planarization process is performed, e.g., a chemical mechanical polish (CMP) to reduce the conductive fill to a surface of the dielectric layer 102 to form conductor 106. This CMP process also removes the diffusion barrier 104 from the surface of the dielectric layer 102. The conductor 106 can include a metal line, a via or any other suitable conductive structure. The conductor 106 forms an electrode for the MRAM cell to be fabricated.

A dielectric cap layer 108 is deposited over the conductor 106 and dielectric layer 102. The dielectric cap layer 108 preferably includes a material that is selectively removeable relative to the dielectric layer 102, While the same materials and process used for the dielectric layer 102 can be employed for dielectric cap layer 108, dielectric cap layer 108 includes a different chemistry to enable etch selectivity. For example, if dielectric layer 102 includes a silicon oxide, dielectric cap layer 108 can include a silicon nitride to be selectively etchable with respect to dielectric layer 102. The dielectric cap layer 108 includes a reduced thickness relative to the dielectric layer 102. For example, dielectric cap layer 108 is thick enough to protect the top portion of the conductor 106 during subsequent processing.

Referring to FIG. 2, the dielectric cap layer 108 is patterned to opening 109 through the dielectric layer 108 to expose the conductor 106. The dielectric cap layer 108 can be patterned using lithographic patterning techniques to pattern an etch mask followed by an etching process, such as a reactive ion etch (RIE) or ion beam etch (IBE). The etch process can be selective to the materials of the conductor 106 and the diffusion barrier 104.

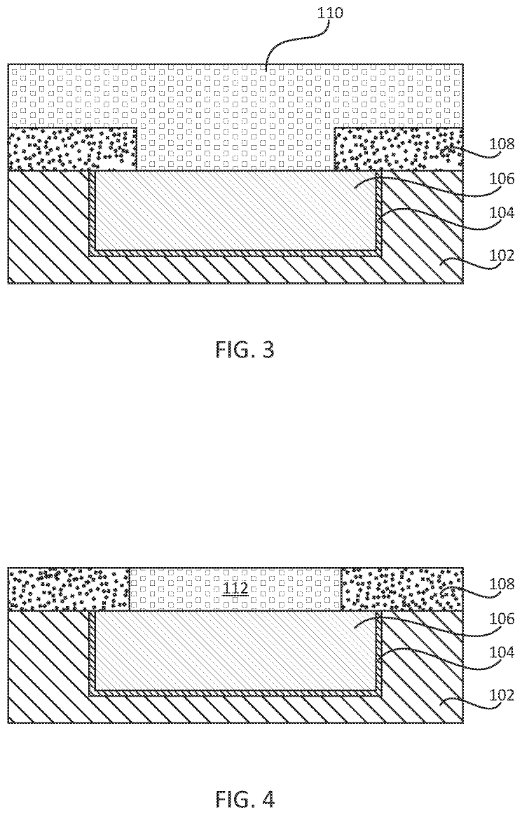

Referring to FIG. 3, a conductive deposition 110 is performed to further fill over the conductor 106. The conductive deposition 110 can include materials, such as, e.g., TaN, TaWN and alloys or combinations of these and other conductive materials. In a particularly useful embodiment, the conductive deposition 110 includes TaN. The conductive deposition 110 can be formed using a deposition method, such as, e.g., CVD, PECVD, ALD, PVD or any other suitable conformal deposition method.

Referring to FIG. 4, a planarization process is performed, e.g., chemical mechanical polishing (CMP), to reduce the conductive deposition 110 to form a cap 112 in the recess over the conductors 106. The cap 112 will provide a conductive path between the conductor 106 and a sloped sidewall bottom electrode (BE) to be formed.

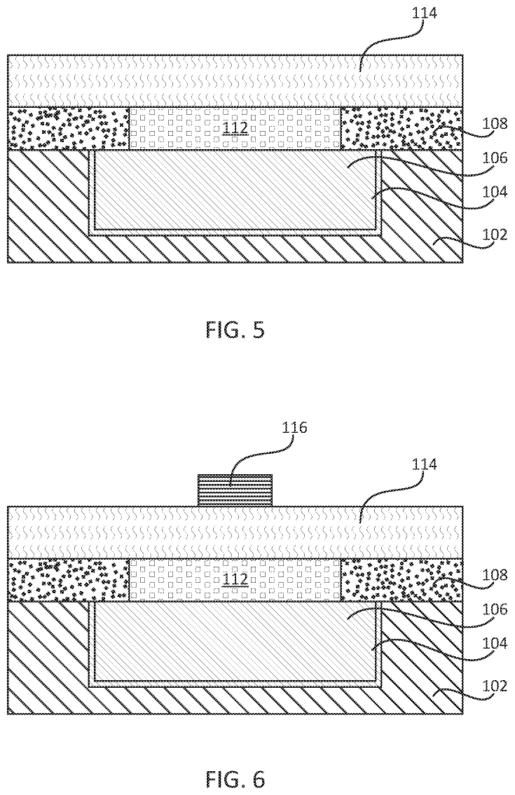

Referring to FIG. 5, a mandrel material 114 can be formed by a deposition process such as, for example, CVD, PECVD or ALD. The mandrel material 114 can include, e.g., amorphous C, amorphous Si, hydrogenated versions of these materials or other selectively removeable materials.

Referring to FIG. 6, in one embodiment, a hard mask 116 includes a hard mask material that may be formed by blanket depositing a layer of the hard mask material, providing a patterned photoresist on top of the layer of hard mask material, and then etching the layer of hard mask material to provide the hard mask 116, which protects a portion of the mandrel material 114, e.g., to form the sloped sidewall bottom electrode directly over the cap 112.

A patterned photoresist can be produced by applying a blanket photoresist layer to the surface of the hard mask material and exposing the photoresist layer to a pattern of radiation, and then developing the pattern into the photoresist layer utilizing resist developer. The hard mask 116 is patterned to a dimension that is narrower than the cap 112, but centered on the cap 112 to ensure the sloped sidewall bottom electrode contacts the cap 112 when formed.

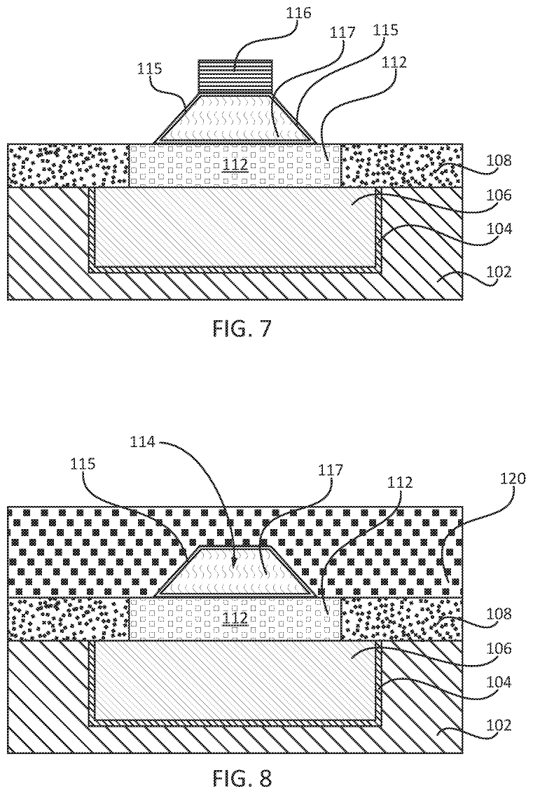

Referring to FIG. 7, a tapered etch of the exposed portion in accordance with the hard mask 116 is performed using an etch chemistry for removing the mandrel material 114 with a selectivity relative to the hard mask 116. The tapered etch produces sloping sidewalls 115 in the mandrel material 114 to provide a shape for a mandrel 117 for the bottom electrode to be formed in accordance with embodiments of the present invention. In one embodiment, the etch process may be an anisotropic etch process, such as RIE or IBE. The sloping sidewalls 115 can have a linear profile, a concave profile or include portions with both profile shapes. Other profile shapes are also contemplated for sloping sidewalls 115.

Referring to FIG. 8, the hard mask 116 is removed. This can be completed using a selective etch relative to the mandrel material 114, cap 112 and the dielectric cap layer 108. In another embodiment, the hard mask 116 can be removed using a planarization process, such as, e.g., CMP.

A dielectric layer 120 is formed on the mandrel 117, portions of the cap 112 and the dielectric cap layer 108. The dielectric layer 120 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 120 can be deposited using CVD, PECVD, spin-on deposition, although other deposition methods can be employed.

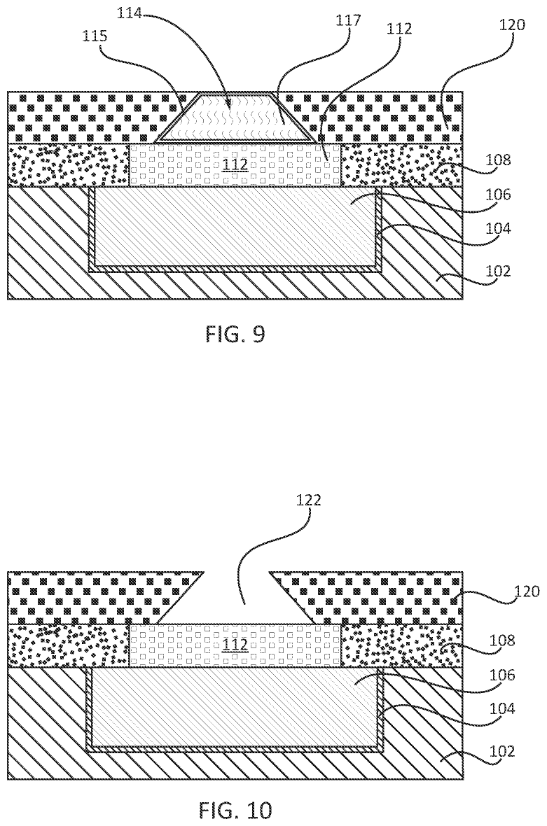

Referring to FIG. 9, the dielectric layer 120 can be planarized to bring the thickness down to a top of the mandrel 117. A planarization process, such as, e.g., CMP can be employed. The dielectric layer 120 will provide a structure from which the mandrel material 114 will be pulled to form a sloped sidewall bottom electrode in the form of the mandrel 117.

Referring to FIG. 10, a mandrel pull process is performed to selectively remove the mandrel 117 from the dielectric layer 120. In one embodiment, the mandrel pull is performed by a selective wet etch that removes the mandrel 117 (e.g., amorphous C) while leaving a void or cavity 122 in the shape of the mandrel 117. The wet etchant can include HF, HBr or other suitable etchants. In other embodiments, a dry etch method can be employed, such as, e.g., RIE. It should be understood that the shape of the mandrel 117 could include a concave side walls, a bar with a trapezoidal cross-section, a cone without an apex or other shape depending on a footprint of the MRAM structure being formed.

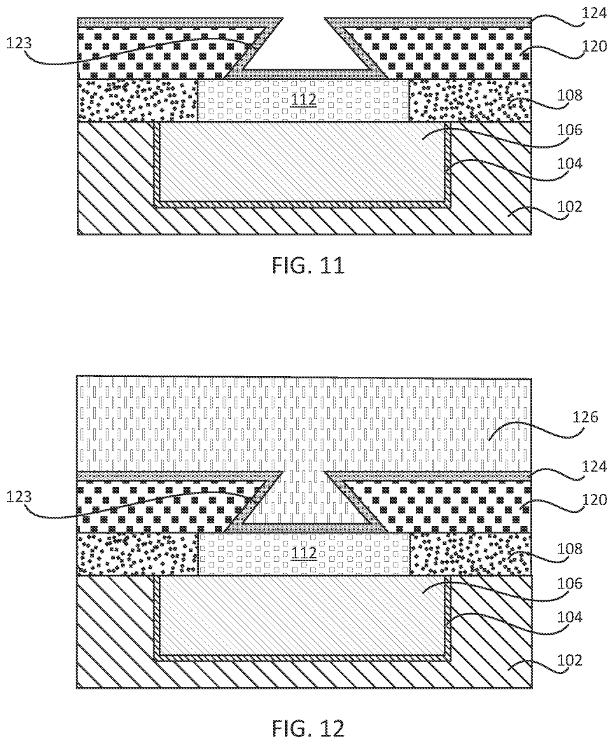

Referring to FIG. 11, a conformal electrode layer 124 is deposited over the dielectric layer 120 and lines the cavity 122. The portion within the cavity 122 will form a sloped sidewall bottom electrode. In one embodiment, the conformal electrode layer 124 includes a metal nitride, such as, e.g., TaN, TiN, WN. In another embodiment, the conformal electrode layer 124 includes a metal, such as, e.g., Ta, Ti, W, Pt, Ru. Combinations of these and other materials can also be employed. The conformal electrode layer 124 can be deposited using, e.g., CVD or ALD, although other methods can also be employed.

Referring to FIG. 12, a layer of dielectric material 126 is formed on the conformal electrode layer 124 and fills an available volume within the cavity 122. The dielectric material 126 enters the open cavity 122 and fills inside of the cavity 122 within the bounds created by sloped sidewalls 123 of the of the conformal electrode layer 124. The dielectric material 126 can include, e.g., SiON, AlON or SiO₂. In other embodiments, metal oxides, such as, e.g., TiO₂, Al₂O₃, HfO₂ can be employed for dielectric material 126. The dielectric material 126 can be deposited using, e.g., CVD, PECVD or ALD, although other deposition methods can be employed.

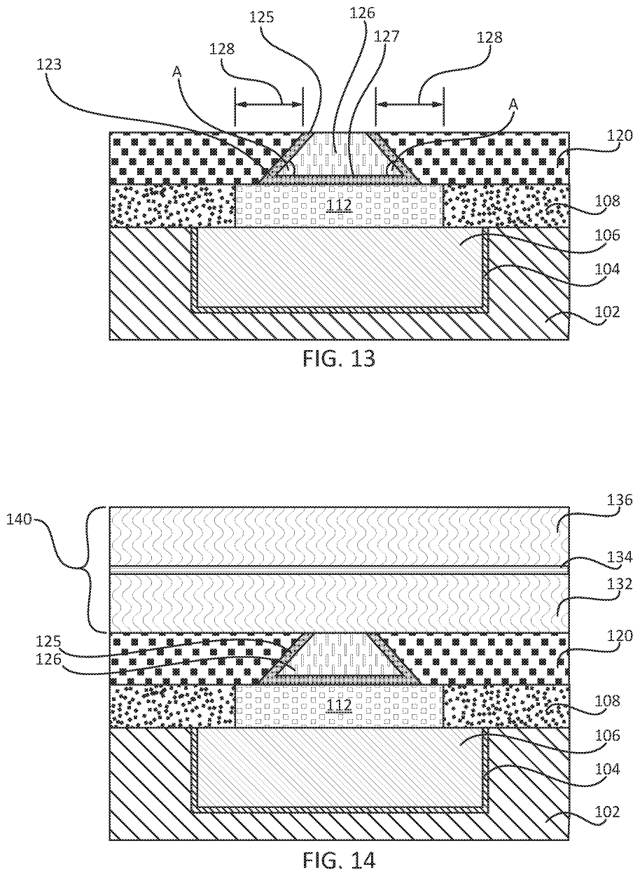

Referring to FIG. 13, the dielectric material 126 can be planarized to bring the thickness down to the conformal electrode layer 124 and to remove the conformal electrode layer 124 from regions outside the cavity 122 (FIG. 11). The conformal electrode layer 124 is removed from a surface of the dielectric layer 120 to form a sloped sidewall bottom electrode 125. The sloped sidewall bottom electrode 125 slopes in regions 128 to provide more dielectric materials on side of the sloped sidewall bottom electrode 125. In addition, far less conductive material is present in regions 128. This will reduce the risk of re-sputtering of bottom electrode materials when an MTJ and bottom electrode stack are patterned in later steps. A planarization process, such as, e.g., CMP can be employed to planarize the dielectric material 126 and the conformal electrode layer 124.

The conformal electrode layer 124 forms a structure having an outer shell. The sloped sidewalls 123 form an acute angle A with a bottom portion 127. The bottom portion 127 connects the sloped sidewalls 123 leaving a top portion open,

Referring to FIG. 14, a ferromagnetic layer 132 is deposited over the sloped sidewall bottom electrode 125. The ferromagnetic layer 132 can include, for example, a composition including cobalt (Co), iron (Fe), nickel (Ni), boron (B), or any combination thereof. In one example, the ferromagnetic layer 132 includes a reference layer (RL) with a fixed magnetization that can be formed of, e.g., CoFeB or CoFe. The ferromagnetic layer 132 can be formed by a deposition process such as, for example, PVD, CVD or PECVD.

A tunnel barrier dielectric layer 134 is formed on the ferromagnetic layer 132. The tunnel barrier dielectric layer 134 is the site of tunnel magnetoresistance (TMR), which is the magnetoresistive effect that occurs in the MTJ structure. The tunnel barrier dielectric layer 134 can be formed of a non-magnetic, insulating material such as magnesium oxide (MgO), aluminum oxide (Al₂O₃), tantalum oxide (Ta₂O₅) or titanium oxide (TiO₂) or any other suitable materials. The tunnel barrier dielectric layer 134 may have a thickness ranging from about 0.5 nm to about 1.0 nm. The tunnel barrier dielectric layer 134 can be formed by a deposition process such as, for example, PVD, CVD or ALD.

A ferromagnetic layer 136 is deposited on the tunnel barrier dielectric layer 134. The ferromagnetic layer 136 can include, for example, a composition including cobalt (Co), iron (Fe), nickel (Ni), boron (B), or any combination thereof. In one example, the ferromagnetic layer 136 includes free magnetization layer (FL) and can be formed of, e.g., CoFeB or CoFe. The ferromagnetic layer 136 can be formed by a deposition process such as, for example, PVD, CVD or PECVD. The ferromagnetic layer 132, the tunnel barrier dielectric layer 134, ferromagnetic layer 136 form a magnetic tunnel junction (MTJ) stack 140.

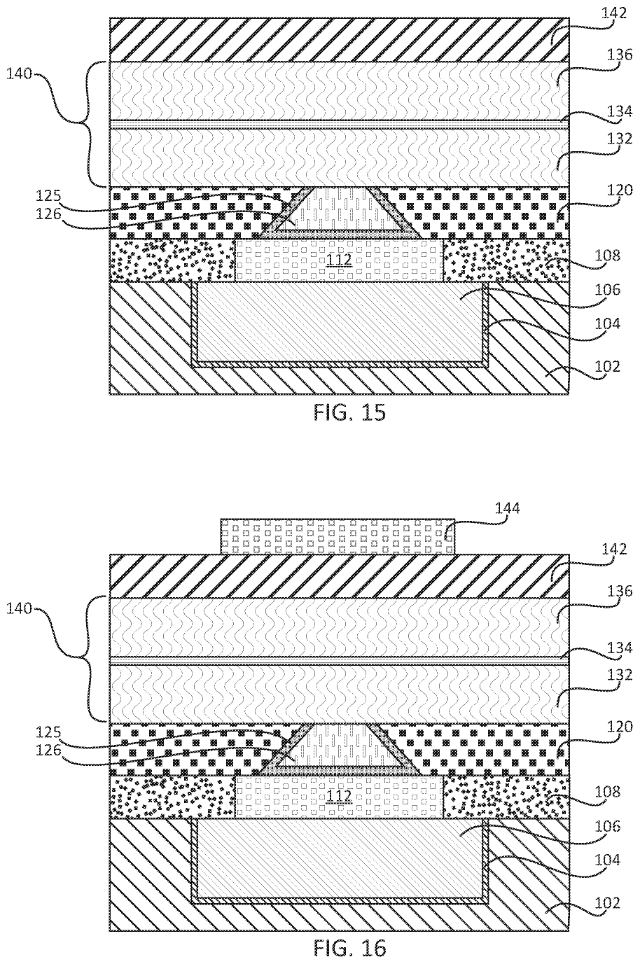

Referring to FIG. 15, a conductive material 142 can be formed by a deposition process such as, for example, sputtering, CVD, or PECVD. The conductive material 142 can include Ta, TaN, Ti, TiN, Ru, RuN, RuTa, RuTaN, W, WN and alloys or combinations of these and other conductive materials. In one embodiment of the present application, conductive material 142 is composed of Ti/TiN. The conductive material 142 (that provides a top electrode) can be compositionally the same as, or compositionally different from, the conductive material that provides the sloped sidewall bottom electrode 125.

Referring to FIG. 16, in one embodiment, a hard mask 144 includes a hard mask material that may be formed by blanket depositing a layer of the hard mask material, providing a patterned photoresist on top of the layer of hard mask material, and then etching the layer of hard mask material to provide the hard mask 144, which protects a portion of the conductive material 142, e.g., to form a top electrode. The hard mask 144 is patterned to a dimension that is narrower than the MTJ stack 140, but centered over the sloped sidewall bottom electrode 125.

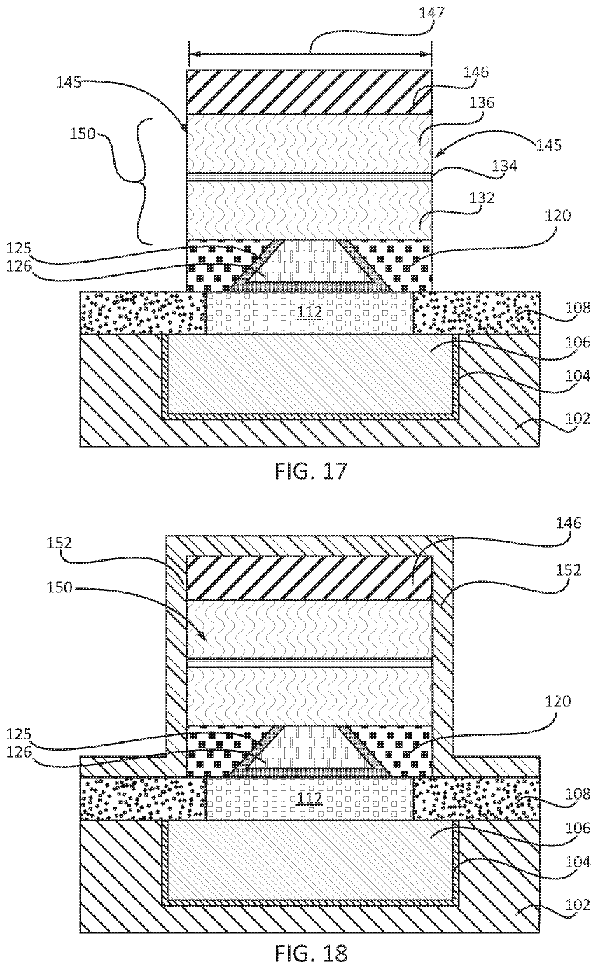

Referring to FIG. 17, a top electrode 146 is etched into the conductive material 142 in accordance with the hard mask 144. The hard mask 144 is employed to etch the ferromagnetic layer 136, the tunnel barrier dielectric layer 134, and the ferromagnetic layer 132 to form a magnetic tunnel junction (MTJ) 150, in accordance with the hard mask 144 pattern. The hard mask 144 is further employed to etch the dielectric layer 120. During the etching of the dielectric layer 120, there is no etching of a conductive material that would otherwise be re-sputtered and deposit itself on sidewalls of the MTJ 150.

In accordance with embodiments of the present invention, the sloped sidewall bottom electrode 125 is recessed and occupies a central portion of the dielectric layer 120. As such, only dielectric layer 120 is etched layer after sidewalls 145 of the MTJ 150 have been patterned. The sidewalls 145 define a periphery 147 of the MTJ 150. Portions of the dielectric layer 108 extend beyond the periphery; however, no portion of the sloped sidewalls back electrode 125 are present in this region. Therefore, there is no additional etching or conductive material formation until after a dielectric encapsulation layer is applied to the MTJ in a later step. The resulting structure will exhibit no tunnel barrier shorts since no bottom electrode metal re-sputtering can occur during MTJ patterning. The hard mask 144 is then removed. This can be completed using a selective etch or a planarization process, such as, e.g., CMP.

Referring to FIG. 18, a dielectric encapsulation layer 152 is conformally formed over the top electrode and sidewalls of the MTJ 150, dielectric layer 120 and dielectric layer 108. The dielectric encapsulation layer 152 will be employed to form sidewall spacers in contact with the sidewalls of the MTJ 150. The dielectric encapsulation layer 152 can be formed by depositing a conformal layer of dielectric material, such as oxide, nitride or oxynitride. In particularly useful embodiments, the dielectric encapsulation layer 152 can include SiN, SiNC or other suitable materials. The dielectric encapsulation layer 152 can be deposited using, e.g., a CVD method.

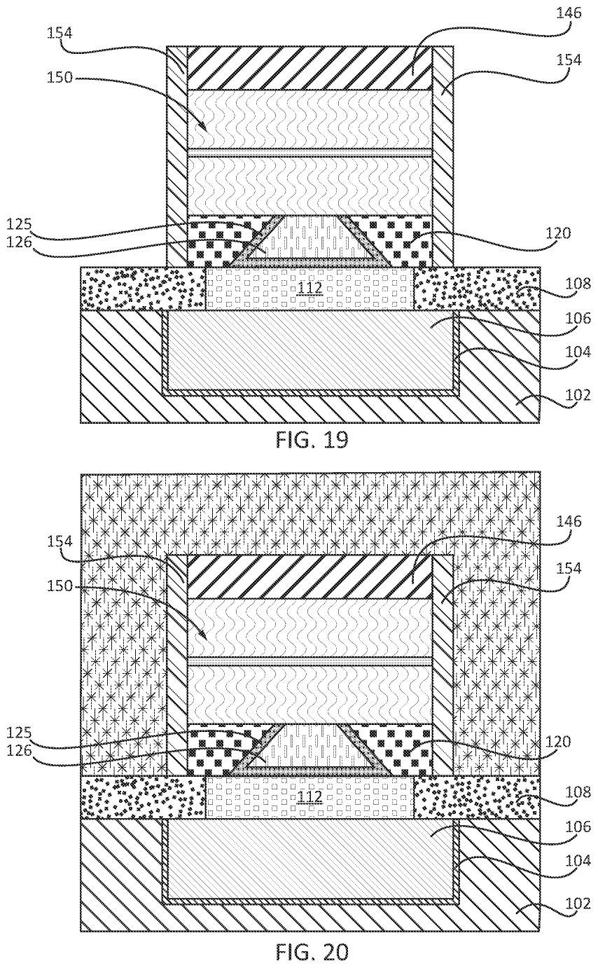

Referring to FIG. 19, an etch-back process is performed to remove the dielectric encapsulation layer 152 from the dielectric layer 108 and the top electrode 146. The dielectric encapsulation layer 152 remains of the sidewalls of the MTJ 150 and dielectric layer 120 to form sidewall spacers 154. The etch-back process can include an RIE or IBE process.

Referring to FIG. 20, a dielectric layer 160 is deposited. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, PECVD, spin-on deposition, although other deposition methods can be employed.

Referring to FIG. 21, the dielectric layer 160 is patterned and etched to form holes or trenches. The trenches may then be lined with a metal liner or diffusion barrier 162. The diffusion barrier 162 can be conformally deposited over the topography of the dielectric layer 160. The diffusion barrier 162 can be deposited by an ALD process or a CVD process, although other processes may be employed. The diffusion barrier 162 can include a material such as, e.g., TiN, TaN, TiWN, TaWN, HfN or the like.

A conductive fill is performed to fill the trench on top of the diffusion barrier 162. The conductive fill can include materials, such as, e.g., Cu, Ru, Mo, Rh, W, Ir, and alloys or combinations of these and other conductive materials. In a particularly useful embodiment, the conductive fill includes Ru. The conductive fill can be formed using a deposition method, such as, e.g., PVD, CVD, PECVD, ALD or any other suitable deposition method.

A planarization process is performed, e.g., CMP, to reduce the conductive fill to a surface of the dielectric layer 160 to form conductor 170. This CMP process also removes the diffusion barrier 162 from the surface of the dielectric layer 160. The conductor 170 can include metal lines, vias or any other suitable conductive structure.

Device pillar structure 172 forms a memory storage portion of a MRAM cell that can employ spin-transfer torque (STT) phenomenon realized in the MTJ 150, wherein the free layer 136 has a non-fixed magnetization, and the pinned or reference layer 132 has a fixed magnetization. The MTJ 150 stores information by switching the magnetization state of the free layer 136. A resistance of the whole MTJ 150 changes when the magnetization of the free layer 136 changes direction relative to that of the fixed layer 132, exhibiting a low resistance state when the magnetization orientation of the two ferromagnetic layers is substantially parallel and a high resistance when they are anti-parallel. Therefore, the cells have two stable states that allow the cells to serve as non-volatile memory elements.

Device pillar structures 172 forming memory portions of MRAM cells are formed into arrays on a chip, which are connected by metal word and bit lines (e.g., conductors 106, 170). Each memory cell (associated with device pillar structures 172) is connected to a word line and a bit line (e.g., conductors 106 and 170). The word lines connect rows of cells, and bit lines connect columns of cells. A selection transistor (not shown) can be electrically connected to the MTJ 150 through the top electrode 146 or the sloped sidewall bottom electrode 125.

The sloped sidewall bottom electrode 125 formed in accordance with embodiments of the present invention includes a shape and position that avoids any conductive material being in an etch region after the MTJ 150 is patterned. The sloped sidewall bottom electrode 125 is filled with a dielectric material 126; however, in other embodiments the sloped sidewall bottom electrode 125 can include a greater amount of conductive material.

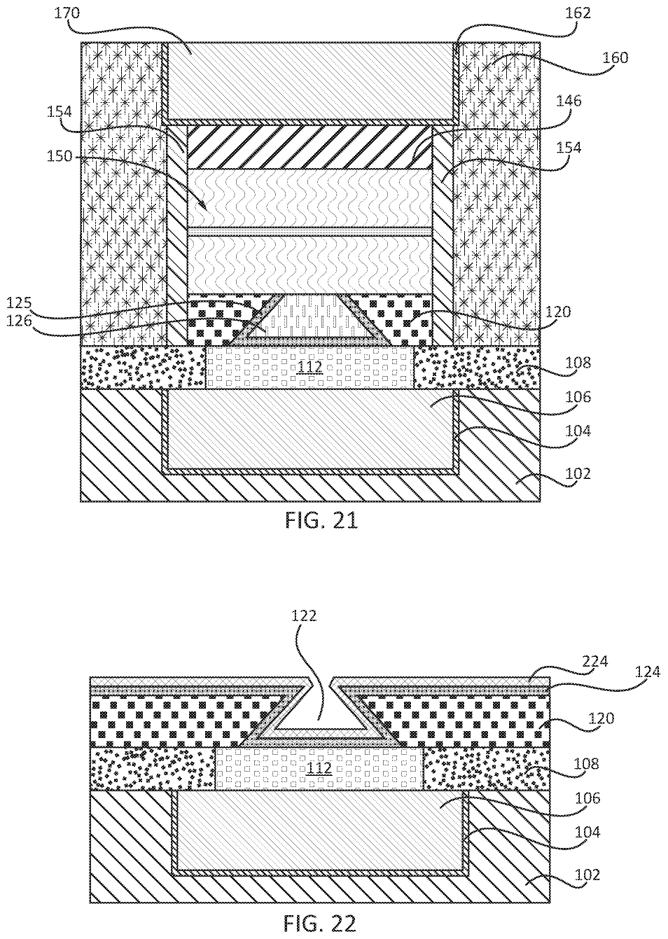

Referring to FIG. 22, in another embodiment, multiple conductive materials can be conformally deposited to form a sloped sidewall bottom electrode 225 (FIG. 24). Beginning with the structure of FIG. 11, a conformal electrode layer 224 can be deposited over the conformal electrode layer 124. In one embodiment, the conformal electrode layer 224 includes a metal nitride, such as, e.g., TaN, TiN, WN. In another embodiment, the conformal electrode layer 224 includes a metal, such as, e.g., Ta, Ti, W, Pt, Ru. Combinations of these and other materials can also be employed. The conformal electrode layer 224 can be deposited using, e.g., CVD or ALD, although other methods can also be employed. The conformal electrode layer 224 can include a same material or a different material than the conformal electrode layer 124.

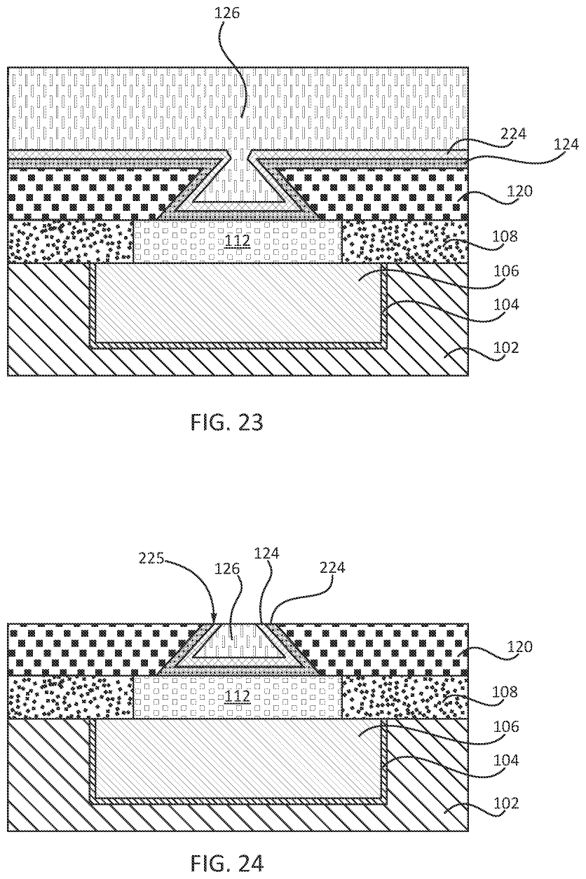

Referring to FIG. 23, the dielectric material 126 is formed as before but now on the conformal electrode layer 224. The dielectric layer 226 and fills available space within the cavity 122.

Referring to FIG. 24, the dielectric material 126 can be planarized to bring the thickness down to the conformal electrode layer 224 and to remove the conformal electrode layers 124 and 224 from regions outside the cavity 122 (FIG. 22). The conformal electrode layers 124, 224 are removed from a surface of the dielectric layer 120 to form a sloped sidewall bottom electrode 225 having more than one layer of conductive material. Additional layers can be formed depending on the size and shape of the cavity 122. The sloped sidewall bottom electrode 225 avoids re-sputtering of bottom electrode materials when an MTJ and bottom electrode stack are patterned in later steps.

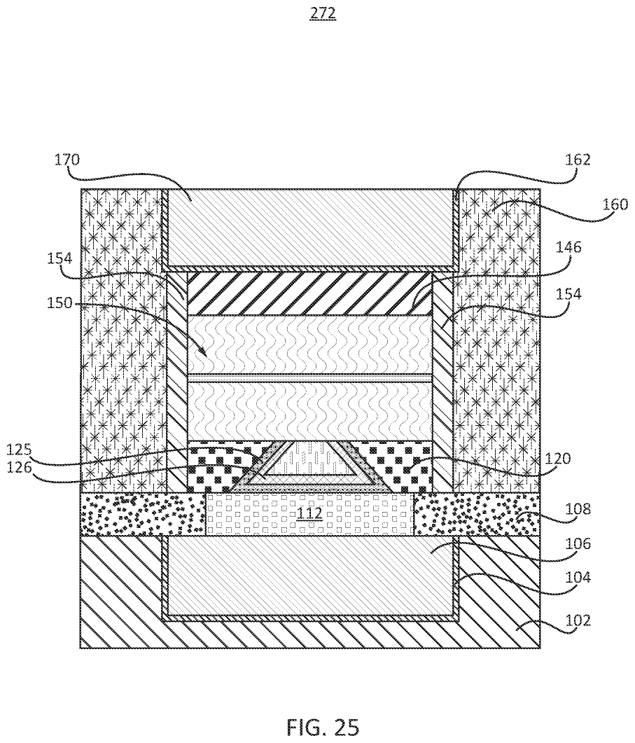

Referring to FIG. 25, a device pillar structure 272, which forms a memory storage portion of an MRAM cell is depicted having a multi-layer bottom electrode 225. This device pillar structure exhibits no tunnel barrier shorts due to re-sputtering of bottom electrode conductive materials.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A magnetoresistive random access memory (MRAM), comprising:
a magnetic tunnel junction (MTJ) having a reference layer, a free layer and a tunnel barrier disposed between the reference layer and the free layer; and
a bottom electrode being centrally disposed to be located within a periphery of the MTJ, the bottom electrode having sloped sidewalls that slope inwardly to connect to the MTJ.

2. The MRAM as recited in claim 1, wherein the sloped sidewalls define a volume, the volume being filled with a dielectric material.

3. The MRAM as recited in claim 1, wherein the bottom electrode is disposed within a dielectric layer and the dielectric layer extends to the periphery of the MTJ.

4. The MRAM as recited in claim 3, wherein the dielectric layer is free of the bottom electrode outside the periphery.

5. The MRAM as recited in claim 1, wherein the sloped sidewalls form an acute angle with a bottom portion of the bottom electrode.

6. The MRAM as recited in claim 1, wherein the sloped sidewalls include a concave profile.

7. The MRAM as recited in claim 1, wherein the bottom electrode includes at least two layers of conductive material.

8. The MRAM as recited in claim 7, wherein the at least two layers of conductive material include at least two layers of different conductive materials.

9. A magnetoresistive random access memory (MRAM), comprising:
a metal cap;
a bottom electrode having sloped sidewalls that define a dielectric-filled volume; and
a magnetic tunnel junction (MTJ) having a reference layer, a free layer and a tunnel barrier disposed between the reference layer and the free layer, the MTJ having a periphery;
the bottom electrode being centrally disposed to be located within the periphery, the sloped sidewalls sloping inwardly to connect to the MTJ and outwardly to connect to the metal cap.

10. The MRAM as recited in claim 9, wherein the bottom electrode is disposed within a dielectric layer and the dielectric layer extends to the periphery of the MTJ.

11. The MRAM as recited in claim 10, wherein the dielectric layer is free of the bottom electrode outside the periphery.

12. The MRAM as recited in claim 10, wherein the sloped sidewalls of the bottom electrode are connected at a bottom portion of the bottom electrode.

13. The MRAM as recited in claim 10, wherein the sloped sidewalls include a concave profile.

14. The MRAM as recited in claim 10, wherein the bottom electrode includes at least two layers of conductive material.

15. The MRAM as recited in claim 14, wherein the at least two layers of conductive material include at least two layers of different conductive materials.

16. The MRAM as recited in claim 10, wherein the sloped sidewalls form an acute angle with a bottom portion of the bottom electrode.

17. A magnetoresistive random access memory (MRAM), comprising:
a bottom electrode on a metal cap, the bottom electrode having sloped sidewalls that define a dielectric-filled volume, the bottom electrode being centrally disposed on the metal cap and having sloped sidewalls sloping inwardly to connect to a ferromagnetic layer.

18. The MRAM as recited in claim 17, wherein the bottom electrode is disposed within a dielectric layer and the dielectric layer extends to a periphery of the ferromagnetic layer, the dielectric layer being free of material of the bottom electrode outside the periphery.

19. The MRAM as recited in claim 17, wherein the sloped sidewalls include a concave profile.

20. The MRAM as recited in claim 17, wherein the bottom electrode includes at least two layers of conductive material.
